(19) United States
(12) Patent Application Publication
(10) Pub. No.: US 2026/0159638 A1
(43) Pub. Date: Jun. 11, 2026

(54) CURABLE COMPOSITION AND INSULATING FILM

(71) Applicant: DUPONT ELECTRONICS, INC., WILMINGTON, DE (US)

(72) Inventors: CHU-YI LEE, HSINCHU (TW); YU-TE LIAO, HSINCHU (TW); YU-CHENG CHEN, HSINCHU (TW)

(21) Appl. No.: 19/408,913

(22) Filed: Dec. 4, 2025

Related U.S. Application Data
(60) Provisional application No. 63/730,231, filed on Dec. 10, 2024.

(51) Int. Cl. C08G 59/40; C08G 59/24; C08G 59/42; C08G 59/62; C08G 59/68; C08K 3/38; H05K 1/02; H05K 3/00

(52) U.S. Cl. CPC C08G 59/4042; C08G 59/245; C08G 59/4276; C08G 59/621; C08G 59/686; C08K 3/38; H05K 1/0256; C08K 2003/385; C08K 2201/005; H05K 3/0041; H05K 2201/0166; H05K 2201/0179; H05K 2201/0209; H05K 2201/0266

(57) ABSTRACT

The present disclosure provides a curable composition comprising (a) an epoxy resin; (b) a hardener; (c) a curing catalyst; (d) boron nitride as fillers; and (e) an optional additive. The present disclosure also provides an insulating film comprising the aforementioned curable composition, which are particularly suited for manufacturing printed circuit boards (PCBs). The insulating film exhibit excellent electrical properties, including low dissipation factor (Df) and a low coefficient of thermal expansion (CTE). Furthermore, the insulating film provides significant advantages in reducing the production time in PCB manufacturing processes that involve a plasma etching step.

### FIELD OF THE DISCLOSURE

The disclosure relates in general to a curable composition containing boron nitride, and more particularly to an insulating film and/or a print circuit board comprising the same.

### BACKGROUND OF THE DISCLOSURE

Due to the current trend towards thinner and lighter electronic products, print circuit boards (PCBs) must have higher wiring density. PCB is generally composed of multiple insulating and conductive layers stacked on top of each other. To achieve high wiring density, through holes or blind holes are provided to connect circuit between different conductive layers.

The conventional via fabricating technology uses laser light as a drilling tool. The friction generated by drilling creates a resin smear on the channel walls. This smear must be removed to enable an optimal connection. Generally, a wet process is employed after laser drilling to remove smear and form suitable through holes. This wet process includes surface cleaning, swelling the smear, permanganate de-smear, and neutralization reaction. However, the waste liquid and waste water discharged in each step carry away a large amount of harmful substances, and may worsen the environment and impose damages to human's physical and mental health.

Compared to the subtractive or (modified) semi-additive process in PCB manufacturing, forming pattern and/or via by plasma etching is considered a more environmentally friendly process since it does not involve a wet process. However, the etching rate of plasma etching is typically too slow to be cost-effective for manufacturing PCBs. For example, US Patent Publication No. 20220201853 A1 discloses using plasma etching to manufacture a multi-layer circuit structure having embedded circuit layers, but the material tested in this prior art demonstrated an etching rate of less than 1.0 μm/min.

In view of the above, there exists a need to develop new materials for PCB insulting layers and the ability to be treated with a plasma etching process brings overall benefits to the printed circuit board industry.

### SUMMARY

To solve the aforementioned problems, the present disclosure provides a novel composition for an insulating layer of PCB. PCB composed with this material has higher plasma etching rate without sacrificing its electrical and mechanical properties, such as dissipation factor (Df) and the coefficient of thermal expansion (CTE). The novel composition is a viable alternative to conventional PCB insulating layer.

According to one aspect of the present disclosure, a curable composition is provided. The curable composition comprises:
100 parts by weight of an epoxy resin having an average epoxy equivalent weight of 500 g/eq or less;
35-300 parts by weight of a hardener;
0.025-20 parts by weight of a curing catalyst; and
50-420 parts by weight of a filler, wherein the filler comprises boron nitride and has a median particle size of 8 μm or less, and has a maximum particle size of at most 20 μm.

According to the second aspect of the present disclosure, an insulating film comprising the aforementioned curable composition is also provided. The insulating film comprises sequentially a support film, a resin layer composed of the above curable composition, and a protective film. The resin layer has a thickness of 10 μm to 60 μm.

According to the third aspect of the present disclosure, a printed circuit board is also provided. The PCB comprises an insulating layer that is a cured product of the above curable composition or is made from the above insulating film.

### BRIEF DESCRIPTION OF THE DRAWINGS

FIG. 1 shows a section view of the testing coupon according to one embodiment of the present disclosure.

### DETAILED DESCRIPTION

Before addressing details of embodiments described below, some terms are defined or clarified.

### Definitions

All publications, patent applications, patents and other references mentioned herein, if not otherwise indicated, are explicitly incorporated by reference herein in their entirety for all purposes as if fully set forth.

Unless otherwise defined, all technical and scientific terms used herein have the same meaning as commonly understood by one of ordinary skill in the art to which this disclosure belongs. In case of conflict, the present specification, including definitions, prevails.

Unless stated otherwise, all percentages, parts, ratios, etc., are by weight.

As used herein, the term “produced from” is synonymous to “comprising”. As used herein, the terms “comprises,” “comprising,” “includes,” “including,” “has,” “having,” “contains” or “containing,” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus.

The transitional phrase “consisting of” excludes any element, step, or ingredient not specified. If in the claim, such a phrase would restrict the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, method or apparatus that includes materials, steps, features, components, or elements, in addition to those literally discussed, provided that these additional materials, steps features, components, or elements do not materially affect the basic and novel characteristic(s) of the claimed disclosure.

The term “consisting essentially of” occupies a middle ground between “comprising” and “consisting of”.

The term “comprising” is intended to include embodiments encompassed by the terms “consisting essentially of” and “consisting of”. Similarly, the term “consisting essentially of” is intended to include embodiments encompassed by the term “consisting of”.

The epoxy equivalent weight (EEW) is the weight of uncured resin in grams which contains the equivalent of one mole of an epoxy group (g/eq). EEW is dependent upon molecular weight and is useful in determining curing agent concentrations.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. For example, when a range of “1 to 5” is recited, the recited range should be construed as including ranges “1 to 4”, “1 to 3”, “1-2”, “1-2 & 4-5”, “1-3 & 5”, and the like.

Where a range of numerical values is recited herein, unless otherwise stated, the range is intended to include the endpoints thereof, and all integers and fractions within the range.

Further, unless expressly stated to the contrary, “or” refers to an inclusive “or” and not to an exclusive “or”. For example, a condition A “or” B is satisfied by any one of the following: A is true (or present) and B is false (or not present), A is false (or not present) and B is true (or present), and both A and B are true (or present).

The disclosure is described in detail herein under.

The present disclosure relates to a curable composition comprises:
100 parts by weight of an epoxy resin having an average epoxy equivalent weight of 500 g/eq or less;
35-300 parts by weight of a hardener;
0.025-20 parts by weight of a curing catalyst; and
50-420 parts by weight of a filler, wherein the filler comprises boron nitride and has a median particle size of 8 μm or less, and has a maximum particle size of at most 20 μm.

In one embodiment of the present disclosure, the curable composition further comprises an additive of no more than 70 parts by weight per 100 parts by weight of the epoxy resin. In another embodiment of the present disclosure, the curable composition further comprises an additive of 25-70 parts by weight per 100 parts by weight of the epoxy resin.

Non-limiting examples of the epoxy resin comprise a bisphenol A type epoxy, a bisphenol F type epoxy, a glycidyl amine type epoxy, a biphenyl type epoxy, a naphthalene type epoxy, an anthracene type epoxy, a fluorene type epoxy, a biphenyl aralkylphenol type epoxy, a dicyclopentadiene type epoxy, a trihydroxyphenylmethane type epoxy, a naphthol aralkyl type epoxy, a phenol aralkyl type epoxy, a phenol novolac type epoxy, a cresol novolac type epoxy, a bisphenol novolac type epoxy, a naphthol-cresol novolac type epoxy, a naphthalenediol novolac type epoxy, a hydrogenated or halogen modified epoxy. However, in one embodiment of the present disclosure, the epoxy resin is selected from the group consisting of the above epoxy resins and a mixture thereof.

Non-limiting examples of the hardener comprise an active ester type hardener, a carbodiimde type hardener, a phenol type hardener, a naphthol type hardener or an acid type hardener. However, in one embodiment of the present disclosure, the hardener is selected from the group consisting of the above hardeners and a mixture thereof.

In one embodiment of the present disclosure, the hardener is free of cyanate resin. In one embodiment of the present disclosure, the hardener comprises active ester type hardener.

In one embodiment of the present disclosure, the curable composition comprises 40-200 parts by weight of a hardener per 100 parts by weight of the epoxy resin. In another embodiment of the present disclosure, the curable composition comprises 40-100 parts by weight of a hardener per 100 parts by weight of the epoxy resin.

Non-limiting examples of the curing catalyst comprise an alkyl amine type catalyst, a pyridine type catalyst, an imidazole type catalyst or a piperidine type catalyst. However, in one embodiment of the present disclosure, the curing catalyst is selected from the group consisting of the above curing catalysts and a mixture thereof.

Non-limiting examples of the additive comprise antioxidants, flame retardants, coloring agents, thickeners, defoamers, elastomers, surface conditioners, polymerization inhibitors, ultraviolet absorbers, solvents, silane coupling agents, adhesion promoters or antioxidants. However, in one embodiment of the present disclosure, the additive is selected from the group consisting of the above additives and a mixture thereof.

In one embodiment of the present disclosure, the amount of the additive is no more than 70 parts by weight.

In one embodiment of the present disclosure, the additive is at least one solvent selected from the group consisting of methyl ethyl ketone, toluene, cyclohexanone, cyclopentanone, isophorone, methyl isobutyl ketone, and a mixture thereof.

In one embodiment of the present disclosure, the curable composition comprises 50-350 parts by weight of a filler per 100 parts by weight of the epoxy resin. In another embodiment of the present disclosure, the curable composition comprises 100-300 parts by weight of a filler per 100 parts by weight of the epoxy resin. In another embodiment of the present disclosure, the curable composition comprises 160-300 parts by weight of a filler per 100 parts by weight of the epoxy resin.

The second aspect of the present disclosure is related to an insulating film for fabricating a printed circuit board, especially suitable for applying a plasma etching. The insulating film comprising sequentially:
a support film;
a resin layer composed of the above curable composition; and
a protective film.

In one embodiment of the present disclosure, the resin layer has a thickness of 10 μm to 60 μm. In another embodiment of the present disclosure, the support film is a thermoplastic film having a thickness of 10 μm to 50 μm, or a metallic foil having a thickness of 1 μm to 25 μm. In another embodiment of the present disclosure, the protective film is a thermoplastic film having a thickness of 10 μm to 50 μm.

In one embodiment of the present disclosure, the support film and the protective film are each independently composed of a polymeric material selected from the group consisting of polyethylene, polypropylene, polyvinyl chloride, polyethylene terephthalate, polyethylene naphthalate, polycarbonate, and polyimide.

In one embodiment of the present disclosure, the support film is a metallic foil selected from the group consisting of Au, Ag, Cu, Al, and alloys thereof.

In one embodiment of the present disclosure, the resin layer is cured at 100° C. to 250° C. for 60 minutes to 240 minutes.

In one embodiment of the present disclosure, the resin layer after curing has a dissipation factor (Df) of 0.006 or less when measured at 10 GHz and 23° C.

In one embodiment of the present disclosure, the resin layer after curing has a coefficient of thermal expansion (CTE) of 40 ppm/K or less between 30° C. to 120° C.

In one embodiment of the present disclosure, the resin layer after curing has a plasma etching rate of 1 μm/min or more, and the plasm etching is performed under a chamber pressure of 2 Pa (15 mtorr) by applying a radiofrequency (RF) power of 13.56 MHz, an ignition power of 8000 Watts, a DC bias of 3000 Watts setting with a gas mixture of oxygen, tetrafluoromethane (carbon tetrafluoride, CF4) and nitrogen at a ratio of 10:10:1, and a flow rate of 1050 mL/see for 15 minutes.

The third aspect of the present disclosure is related to a printed circuit board comprising an insulating layer that is a cured product of the above curable composition or is made from the above insulating film.

In one embodiment of the present disclosure, the printed circuit board comprises a circuit which is fabricated by a method comprising a plasma etching step for via and/or trench formation.

In one embodiment of the present disclosure, the method for forming the circuit is a semi-additive process (SAP) or a modified semi-additive process (mSAP).

### Composition and Film Preparation

The curable composition of the present disclosure comprises the following components: (a) an epoxy resin; (b) a hardener; (c) a curing catalyst; (d) boron nitride as fillers; and (e) an optional additive. In one non-limiting aspect, the composition aspect of the present disclosure may be prepared from the components listed in Table A below. Epoxy resin, Boron Nitride Filler and solvents were mixed and dissolved first, then added the other components including hardener, catalyst and optional additive until they were fully dissolved to form a varnish. The composition was prepared into two different samples: resin coated copper (RCC) film structure and resin sheet structure for more test.

TABLE A

| Type | Manufacturer | Brand and model name | Description | Properties |
|---|---|---|---|---|
| Epoxy | Mitsubishi chemical | jER YL7890 | biphenyl epoxy | Epoxy equivalent ~210 g/eq |
| | Group Corporation | | | |
| Epoxy | Nippon Steel Chemical | ESN-475V | Naphthalene epoxy | Epoxy equivalent ~332 g/eq |
| Hardener | Nisshinbo | Carbodilite V03 | Carbodiimide | 50% in Toluene. |
| | | | | Equivalent = 216~217 g/eq |
| Hardener | DIC | phenolite LA1356 | Traizine modified | 60% in MEK |
| | | | phenol novalac | Equivalent ~146 g/eq |
| Hardener | DIC | EPICLON HPC8150- | active ester | 62% in Toluene |
| | | 62T | | Equivalent = 223 g/eq |
| Hardener | Nippon kayaku | Kayahard GPH65 | phenol novalac | Equivalent = 195~205 g/eq |
| Catalyst | Shikoku | Curezol 1B2PZ | 1-benzyl-2- | CAS No. 37734-89-7 |
| | | | phenylimidazole | |
| Filler | Denka | SFP130MC | Fused Silica | D50 = 0.6 μm |
| Filler | Sukgyung AT | SG-SO0700 | Silica | D50 = 1.2 μm |
| Filler | Momentive technologies | PT180 | BN | D50 = 7 μm; maximum |
| | | | | size = 15 μm |
| Filler | Saint-Gobain | PCTP05 | BN | D50 = 1.2 μm; maximum |
| | | | | size = 3 μm |
| support film | Mitsui | MT18FL | copper foil | — |
| protective film | Lintech | 38X | release agent-coated | — |
| | | | PET film | |
| protective film | Oji Film | MA411 | OPP release film | — |

*The median particle size (D50) of boron nitride is measured by a laser scattering particle size distribution analyzer

### Example 1

47 grams of PCTP05 (Boron nitride filler from Saint-Gobain) was mixed with 35 grams of MEK (methyl ethyl ketone), 15 grams of toluene and 23.6 grams of YL7890 (Biphenyl epoxy from Mitsubishi Chemicals). The mixture was stirred for 20 minutes until YL7890 epoxy was completely dissolved. Then, 1 gram of GPH65 (phenol type hardener from Nippon Kayaku), 19.7 grams of HPC-8150 (active ester hardener from DIC, 62% in solution), 0.36 grams of 1B2PZ (catalyst from Shikoku Chemicals) and 4.1 grams of LA-1356 (triazine phenol hardener from DIC, 60% in MEK solution) were added. The mixture was stirred again until all ingredients were fully dissolved.

The last component: 14.5 grams of V03 (carbodiimide from Nisshinbo, 50% in toluene) was added to the mixture and stirred for an additional 30 minutes to get a resin varnish. This hardener is added separately to prevent solvent compatibility issue. In other examples, all the components can be mixed at once.

The resulting resin varnish was coated onto a supporting film MT18FL-3 μm (two-layered copper foil with an upper layer having a thickness of 3 μm and the lower layer having a thickness of 18 μm) using suitable quadruple film applicators (purchased from GMA Machinery, Taiwan) on an automatic coater (model Coatmaster 510, purchased from Erichsen GmbH) at a coating speed of approximately 60 mm/s. The coated film was then dried at 100° C. for 3 minutes in a circulation oven (model DCM704, purchased from Channel Instruments, Taiwan). After drying, the film was covered with 38X (protective film), forming a Resin Coated Copper (RCC) film structure sample.

Additionally, the mixed varnish was coated onto 38X (protective film) and dried at 100° C. for 3 minutes. The dried film was then covered with MA411 (protective film), forming a resin sheet structure.

Thickness of the composition layer was 30 μm in the two structures above.

### Example 2

The composition of example 1, wherein the filler is replaced by PT180 (BN, median particle size is 7 μm) and the amount is the same (47 g).

### Comparative Example 1

The composition of example 1, wherein the filler is replaced by SG-SO0700 (silica) and the amount is the same (47 g).

### Comparative Example 2

The composition of example 1, wherein the filler is replaced by SFP130MC (silica) and the amount is the same (47 g).

### Example 3

The composition of example 1, wherein the filler is replaced by 70 g PT180 (BN) and the epoxy is replaced by 23.6 g ESN-475V (α-naphthol aralkyl epoxy resin manufactured by Nippon Steel Chemical Co., Ltd.).

### Example 4

The composition of example 3, wherein the filler is adjusted to 47 g PT180 (BN).

### Example 5

The composition of example 3, wherein the filler is adjusted to 25 g PT180 (BN).

### Comparative Example 3

The composition of example 3, wherein filler is replaced by SFP130MC (silica) and the amount is 87 g.

### Comparative Example 4

The composition of example 3, wherein filler is replaced by SFP130MC (silica) and the amount is 47 g.

### Comparative Example 5

The composition of example 3, wherein filler is replaced by SFP130MC (silica) and the amount is 25 g.

The actual solid content of components of above Examples and Comparative Examples are listed in Table B. The abbreviation “E” stands for “Example”, and “CE” stands for “Comparative Example”. The Examples and Comparative Examples were prepared in a similar manner. The difference between Examples & Comparative Examples lies in the filler. Examples 1-5 uses boron nitride as filler while the Comparative Examples 1-5 uses silica as filler.

TABLE B

| | Brand and | | | | | | | | | | |
|---|---|---|---|---|---|---|---|---|---|---|---|
| Type | model name | E1 | E2 | CE1 | CE2 | E3 | E4 | E5 | CE3 | CE4 | CE5 |
| (a) Epoxy, g | jER YL7890 | 23.6 | 23.6 | 23.6 | 23.6 | — | — | — | — | — | — |
| (a) Epoxy, g | ESN-475V | — | — | — | — | 23.6 | 23.6 | 23.6 | 23.6 | 23.6 | 23.6 |
| (b) Hardener, g | Carbodilite | 7.25 | 7.25 | 7.25 | 7.25 | 7.25 | 7.25 | 7.25 | 7.25 | 7.25 | 7.25 |
| | V03 | | | | | | | | | | |
| (b) Hardener, g | phenolite | 2.45 | 2.45 | 2.45 | 2.45 | 2.45 | 2.45 | 2.45 | 2.45 | 2.45 | 2.45 |
| | LA1356 | | | | | | | | | | |
| (b) Hardener, g | EPICLON | 12.2 | 12.2 | 12.2 | 12.2 | 12.2 | 12.2 | 12.2 | 12.2 | 12.2 | 12.2 |
| | HPC8150- | | | | | | | | | | |
| | 62T | | | | | | | | | | |
| (b) Hardener, g | Kayahard | 1 | 1 | 1 | 1 | 1 | 1 | 1 | 1 | 1 | 1 |
| | GPH65 | | | | | | | | | | |
| (c) Catalyst, g | Curezol | 0.36 | 0.36 | 0.36 | 0.36 | 0.36 | 0.36 | 0.36 | 0.36 | 0.36 | 0.36 |
| | 1B2PZ | | | | | | | | | | |
| (d) Filler, g | SFP130MC | — | — | — | 47 | — | — | — | 87 | 47 | 25 |
| (d) Filler, g | SG-SO0700 | — | — | 47 | — | — | — | — | — | — | — |
| (d) Filler, g | PT180 | — | 47 | — | — | 70 | 47 | 25 | — | — | — |
| (d) Filler, g | PCTP05 | 47 | — | — | — | — | — | — | — | — | — |

| | | | | | | | | | | |
|---|---|---|---|---|---|---|---|---|---|---|
| filler parts by weight | 199.15 | 199.15 | 199.15 | 199.15 | 296.6 | 199.15 | 105.9 | 368.6 | 199.15 | 105.9 |

### Measuring Plasma Etching Rate of the RCC Film

### Testing Coupon Preparation

RCC films of above Examples and Comparative Examples were further processed as follows to prepare a coupon for plasma etching testing:

Lamination: RCC film of size 15 cm×20 cm was laminated on a CZ-8100 (pre-treatment solution made by MEC) pretreated EM526 H/H core board (15 cm×20 cm, 0.6 mm thick) by vacuum laminator. The vacuum laminator was heat to 100° C. and vacuumed for 30 seconds, then pressured to 7 kgf/cm² for 90 seconds at 100° C.

Curing: The laminated sample was cured in an air flow oven with 130° C. for 30 minutes; 180° C. for 30 minutes; and then 200° C. for 90 minutes.

Copper Removal: After curing, the supporting layer MT18FL (carrier copper of RCC film) was removed.

Tenting: a hard mask window (Line/Space pattern of 40 μm/40 μm) was formed on the surface of the cured sample (without the carrier). The sample was then cut to a size of 5 cm×5 cm to serve as the testing coupon.

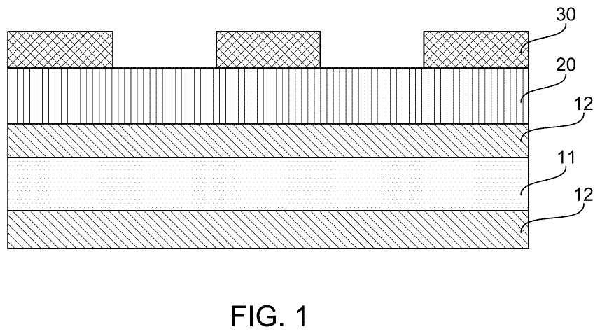

The structure of the testing coupon is shown on FIG. 1. The testing coupon comprises core layer EM526 (11) and its covering copper (12), dielectric layer 20 (curable composition of the present disclosure), and a metal hard mask 30. The following plasma treatment will etch the dielectric layer 20 through the window of the hard mask 30.

### Plasma Etching and Measurement

The coupons of Examples and Comparative Examples were subjected to plasma treatment, and the etching depth was measured using a 3D Optical Microscope (Olympus Lext OLS5100, 50× objective lens). The etching depth is the depth from the surface subtracts the thickness of hard mask. The etching rate was calculated by dividing the etching depth by the processing time. The test results of each coupon are listed in Table C.

TABLE C

| | E1 | E2 | CE1 | CE2 | E3 | E4 | E5 | CE3 | CE4 | CE5 |
|---|---|---|---|---|---|---|---|---|---|---|
| plasma etching rate (μm/min) | 1.8 | 1.76 | 0.88 | 0.67 | 1.84 | 1.49 | 1.37 | 0.62 | 0.7 | 0.8 |

*Plasma Etching Conditions: Ignition 8 kW; Bias 3 kW; RF Frequency 13.56 MHz; Gas flow rates Oxygen 500 cc/min, CF₄ 500 cc/min, N₂ 50 cc/min; Etching duration 15 minutes

As shown in Table C, the plasma etching rate of Examples 1-5 of the present disclosure are greater than 0.9 μm/min. The plasma etching rate can reach greater than 1 μm/min. The plasma etching rate can further reach greater than 1.3 μm/min. In contrast, Comparative Examples 1-5 have relatively low plasma etching rates, and may not be suitable for industry use.

### Measuring Df and CTE of the Resin Sheet

### Sample Preparation

Resin sheets of Examples and Comparative Examples were further processed as follows to prepare a sample for measuring Df and CTE:

Lamination: multiple resin sheets of 10 cm×10 cm size were laminated together to form one dielectric layer with thickness of 60 μm by vacuum laminator. The vacuum laminator was heated to 100° C. and vacuumed for 30 seconds, then pressured to 7 kgf/cm² for 90 seconds at 100° C.
Curing: The laminated sample was cured in an air flow oven with 130° C. for 30 minutes; 180° C. for 30 minutes; and then 200° C. for 90 minutes.
PET film Removal: After curing, the protective layer 38X (PET film) was removed.
Dissipation factor (Df) of the dielectric/insulting layer was measured by resonance cavity method at a frequency of 10 GHz. Coefficient of thermal expansion (CTE) was measured by TA Instruments TMA 650 thermomechanical analyzer. The sample was heated to 280° C., cooled down to room temperature, and then reheated at a rate of 5° C./min with a preload force of 0.098 N. The CTE was calculated from the slope of dimension change to temperature from 50° C. to 100° C. by the second cycle of heating. The test results of each sample are listed in Table D.

TABLE D

| | E1 | E2 | CE1 | CE2 | E3 | E4 | E5 | CE3 | CE4 | CE5 |
|---|---|---|---|---|---|---|---|---|---|---|
| Df @10 GHz (23° C.) | 0.0051 | 0.0057 | 0.0067 | 0.0065 | 0.0029 | 0.0033 | 0.0035 | 0.0031 | 0.004 | 0.0044 |
| CTE (ppm/° C.) | 26.4 | 28.2 | 37.9 | 38 | 13 | 25.3 | 39.8 | 23 | 31.8 | 32.2 |

The curable composition of the present disclosure is particularly suitable for manufacturing printed circuit boards (PCBs).

As shown in Table D, when the filler is replaced from conventional used silica to BN, dissipation factor (Df) and coefficient of thermal expansion (CTE) of Example 1-5 are comparable to those of Comparative Example 1-5. In some Examples, dissipation factor (Df) and coefficient of thermal expansion (CTE) are superior to those of Comparative Examples. For example, the coefficient of thermal expansion can be as low as 13 ppm/° C. The insulating film with the present curable composition exhibits excellent electrical properties, including low dissipation factor (Df) and a low coefficient of thermal expansion (CTE). Furthermore, the insulating film provides significant advantages in reducing the production time in PCB manufacturing processes that involve a plasma etching step.

Making a PCB with the Curable Composition
Step 1: Preparation of Substrate with Existing Electrical Circuits

A PCB board with existing electrical circuits was prepared using EM526 (a core board with a thickness of 64 μm and a copper thickness of 22 μm, supplied by Elite Electronic Material Co. Ltd.).

Step 2: Lamination of RCC coupons on the Substrate

RCC coupons of example 1 were laminated onto the substrate by laminator (Vigor, VLPH-150 ton vacuum laminator). After lamination, the lower layer of the supporting film was removed and the structure from top to bottom consisted of copper, resin, and substrate.

### Step 3: Patterning the Metal to Form a Hard Mask

A photoresist layer was formed by laminating a dry film (Riston® DI61, 15 μm in thickness, manufactured by DuPont Electronics, Inc.) on the copper layer of the substrate from Step 2 using a roll laminator at 100° C., a pressure of 1.4 MPa, and a rolling speed of 1.0 meter/minute.

The photoresist pattern was created using a direct exposure patterning machine (FDi3 from ORC) with a desired pattern. The uncured part of the photoresist layer was stripped and removed by treatment with a 2% Na₂CO₃ solution for 3 minutes, then rinsed with DI water and dried.

The unmasked copper areas were etched away using a sodium persulfate (Na₂S₂O₈) solution (130 g/L) in a conventional horizontal line at 1 m/min speed until completion, followed by rinsing with DI water and drying. The photoresist pattern was then stripped and removed by treatment with a 10% NaOH solution for 90 seconds, followed by rinsing and drying, forming a copper hard mask on the substrate.

### Step 4: Plasma Etching of the Dielectric Layer

The exposed areas of the dielectric layer were removed by plasma etching using a reactive ion etching plasma system (manufactured by Linco Tech). The process gas was a mixture of CF₄ (500 ml/sec), O₂ (500 ml/sec), and N₂ (50 ml/sec), with an ignition power of 8 kW and a DC bias of 3 kW for 20 minutes, to expose a portion of the existing conductor underneath.

### Step 5: Formation of Seed Layer

A seed layer was formed by sputtering copper using a PVD coating machine (manufactured by UVAT Technology Co., model: UHSD-060302T) with fiducial concentrations of copper 4N. The resulting copper layer had a thickness of 0.8 μm.

### Step 6: Addition of Photoresist Pattern Layer

A photoresist layer was formed by laminating a dry film (Riston® DI61, 25 μm in thickness, manufactured by DuPont Electronics, Inc.) on the copper layer using a roll laminator at 100° C., a pressure of 1.4 MPa, and a rolling speed of 1.0 meter/minute.

The photoresist pattern was created using a direct exposure patterning machine (FDi3 from ORC) with a conventional test pattern by the PCB fabricator, including line/space sets at 15 μm/15 μm. The uncured part of the photoresist layer was stripped and removed by treatment with a 2% Na₂CO₃ solution for 3 minutes, rinsed with DI water, and dried.

### Step 7: Filling the Trench and Via by Metal Deposition

Electroplating was applied to fill the trench and via with copper. The coupon was plated to a copper thickness of 22 μm using 23.13 ASF (amplitude per square feet) for 40 minutes with a plating solution (SFP2M from DuPont).

### Step 8: Removal of Photoresist

The photoresist pattern was stripped by treatment with a 10% NaOH solution for 90 seconds.

### Step 9: Removal of Hard Mask Layer

A flash etch to remove the hard mask layer was conducted by:

Dipping the coupon in a 5 vol % sulfuric acid aqueous solution for 20 seconds.

Transferring the coupon to an etchant solution (ST121-M by Chemtronic Technology) for 48 seconds.

Rinsing with DI water to remove residual solution.

After the flash etch process, the new circuit layer with via and conductor line was completed.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A curable composition, comprising:
100 parts by weight of an epoxy resin having an average epoxy equivalent weight of 500 g/eq or less;
35-300 parts by weight of a hardener;
0.025-20 parts by weight of a curing catalyst; and
50-420 parts by weight of a filler, wherein the filler comprises boron nitride and has a median particle size of 8 μm or less, and has a maximum particle size of at most 20 μm.

2. The curable composition of claim 1, wherein the hardener is free of cyanate resin.

3. The curable composition of claim 1, wherein the epoxy resin comprises a bisphenol A type epoxy, a bisphenol F type epoxy, a glycidyl amine type epoxy, a biphenyl type epoxy, a naphthalene type epoxy, an anthracene type epoxy, a fluorene type epoxy, a biphenyl aralkylphenol type epoxy, a dicyclopentadiene type epoxy, a trihydroxyphenylmethane type epoxy, a naphthol aralkyl type epoxy, a phenol aralkyl type epoxy, a phenol novolac type epoxy, a cresol novolac type epoxy, a bisphenol novolac type epoxy, a naphthol-cresol novolac type epoxy, a naphthalenediol novolac type epoxy, a hydrogenated or halogen modified epoxy, or a mixture thereof.

4. The curable composition of claim 1, wherein the hardener comprises an active ester type hardener, a carbodiimde type hardener, a phenol type hardener, a naphthol type hardener, an acid type hardener, or a mixture thereof.

5. The curable composition of claim 1, wherein the curing catalyst comprises an alkyl amine type catalyst, a pyridine type catalyst, an imidazole type catalyst, a piperidine type catalyst, or a mixture thereof.

6. The curable composition of claim 1, wherein the curable composition further comprises an additive of no more than 70 parts by weight and the additive comprises antioxidants, flame retardants, coloring agents, thickeners, defoamers, elastomers, surface conditioners, polymerization inhibitors, ultraviolet absorbers, solvents, silane coupling agents, adhesion promoters, antioxidants or mixtures thereof.

7. The curable composition of claim 1, wherein the additive is at least one solvent selected from the group consisting of methyl ethyl ketone, toluene, cyclohexanone, cyclopentanone, isophorone, and methyl isobutyl ketone, and a mixture thereof.

8. An insulating film suitable for applying plasma etching, comprising a resin layer composed of the curable composition of claim 1, wherein the resin layer has a thickness of 10 μm to 60 μm.

9. The insulating film of claim 8, wherein the insulating film further comprises
a support film and a protective film; and
wherein the resin layer is disposed between the support film and the protective film.

10. The insulating film of claim 9, wherein the support film and the protective film are each independently composed of a polymeric material selected from the group consisting of polyethylene, polypropylene, polyvinyl chloride, polyethylene terephthalate, polyethylene naphthalate, polycarbonate, and polyimide.

11. The insulating film of claim 9, wherein the support film is a metallic foil selected from the group consisting of Au, Ag, Cu, Al, and alloys thereof.

12. The insulating film of claim 8, wherein the resin layer after curing has a dissipation factor (Df) of 0.006 or less when measured at 10 GHz and 23° C., and the curing is conducted at 100° C. to 250° C. for 60 minutes to 240 minutes.

13. The insulating film of claim 8, wherein the resin layer after curing has a coefficient of thermal expansion (CTE) of 40 ppm/K or less between 30° C. to 120° C., and the curing is conducted at 100° C. to 250° C. for 60 minutes to 240 minutes.

14. The insulating film of claim 8, wherein the resin layer after curing has a plasma etching rate of 1 μm/min or more, and the plasma etching is performed under a chamber pressure of 2 Pa by applying a radiofrequency (RF) power of 13.56 MHz, an ignition power of 8000 Watts, a DC bias of 3000 Watts with a gas mixture of oxygen, tetrafluoromethane and nitrogen at a ratio of 10:10:1, and a flow rate of 1050 mL/sec for 15 minutes, and the curing is conducted at 100° C. to 250° C. for 60 minutes to 240 minutes.

15. A printed circuit board, comprising an insulating layer that is a cured product of the curable composition of claim 1.

16. The printed circuit board of claim 15, wherein the printed circuit board comprises a circuit which is fabricated by a method comprising a plasma etching step for via and/or trench formation.
